(19) United States
(12) Patent Application Publication
(10) Pub. No.: US 2026/0337462 A1
(43) Pub. Date: Oct. 29, 2026

(54) Conductive Silicone Adhesive

(71) Applicant: Henkel AG & Co. KGaA, Duesseldorf (DE)

(72) Inventors: Jianfeng Zhang, Irvine, CA (US); Jay Chao, Irvine, CA (US); Qizhuo Zhuo, Irvine, CA (US); Rosette G. Guino, Singapore (SG); Sreevalli Bokka, Irvine, CA (US)

(21) Appl. No.: 19/699,162

(22) Filed: Jun. 5, 2026

Related U.S. Application Data
(63) Continuation of application No. PCT/US2024/059108, filed on Dec. 9, 2024.
(60) Provisional application No. 63/608,496, filed on Dec. 11, 2023.

(51) Int. Cl. C09J 9/02; C08K 3/08; C09J 5/06; C09J 183/04; H05K 1/181; H05K 3/321; H10W 72/00; H10W 72/40; H10W 90/00

(52) U.S. Cl. CPC C09J 9/02; C08K 3/08; C09J 5/06; C09J 183/04; H05K 1/181; H05K 3/321; H10W 72/014; H10W 72/074; H10W 72/07637; H10W 72/40; C08K 2003/0806; C08K 2201/001; C09J 2203/326; C09J 2301/408; C09J 2483/00; H05K 2201/0215; H05K 2201/10189; H05K 2203/1194; H10W 90/761

(57) ABSTRACT

An electrically conductive silicone adhesive that exhibits both high electrical conductivity and high adhesion strength which is useful in providing both bonding and an electrical pathway in electronic packages, also provided is a method of making the electrically conductive silicone adhesive from a curable composition including reactive organosiloxanes and electrically conductive particulate filler.

### FIELD OF THE INVENTION

The present invention relates to electronically conductive adhesives for electronic assemblies generally, and more particularly to curable silicone-based adhesives that exhibit high electrical conductivity and high adhesion strength.

### BACKGROUND OF THE INVENTION

As electronic devices such as semiconductors are produced with increasing complexity and power density, advances are continuously sought for electrically conductive adhesive solutions. Although some conventional electrically conductive materials exhibit high electrical conductivity (low electrical resistance), they tend to exhibit a lower than desired adhesion strength. For example, peeling can occur between the electrically conductive material and the electronic component, which results in an increase in resistance.

Conventionally, electrical conductivity is often a trade-off with adhesive force, wherein high conductivity values in adhesives typically require high filler loading levels, which tend to stiffen the material and reduce adhesion strength. Although efforts have been made to improve both electrical conductivity and adhesion strength in a single solution, known adhesive materials fail to achieve a desirable combination of high electrical conductivity and high adhesion strength. Data taken from literature shows the difficulty of providing a curable, conductive silicone adhesive having both a desirable high electrical conductivity and desirable high adhesion strength.

| | VR | |
|---|---|---|
| | (ohm · cm) | Shear strength |
| PV-5802 (DuPont) | 1.82 × 10⁴ | none found |
| DA6534 (Dow) | 1.80 × 10⁴ | 1.4 MPa (Al) |
| DA6524 (Dow) | 3.00 × 10⁴ | 1.7 Mpa (Al) |
| DA6523 (Dow) | 7.00 × 10⁴ | 2.1 MPa |
| EC-6601 (Dow) | 2.70 × 10³ | 1.7 MPa (Al surface) |
| EC-8425 (Dow) | 1.00 × 10² | 5 MPa (Al/Al) |

The literature shows an inverse relationship between electrical conductivity and adhesion strength with higher electrical conductivity (lower resistance value) compositions having low strengths and high strength compositions having low electrical conductivity (higher electrical resistance). Electrical conductivity is a trade-off with adhesive force, so it is very difficult to provide a curable adhesive having both excellent conductivity and strong adhesion.

Electrical components may be securely affixed in an assembly. Such assemblies, such as electronic devices, can require an adhesive to hold the components in place while allowing effective transfer of electrical energy between selected components.

Accordingly, a need exists for an electrically conductive adhesive composition that is effective in bridging large coefficient of thermal expansion (CTE) mismatch between surfaces while also exhibiting high electrical conductivity and high adhesion strength.

### SUMMARY OF THE INVENTION

One embodiment provides a curable silicone composition for the preparation of electrically conductive silicone adhesives having good electrical conductivity and adhesion strength.

One embodiment provides a curable silicone composition for the preparation of electrically conductive silicone adhesives having good electrical conductivity of 0.01 ohm-cm or less and adhesion strength of greater than 3 MPa.

One embodiment provides a curable silicone composition for the preparation of electrically conductive silicone adhesives having good electrical conductivity of 0.001 ohm-cm or less and adhesion strength of greater than 3 MPa.

One embodiment provides a curable composition for preparing an electrically conductive, curable adhesive including an organosiloxane preparation having a first reactive organosiloxane having at least one unsaturated group, and a second reactive organosiloxane including at least about one silicon hydride functional group and at least about one alkenyl group. In addition to the organosiloxane preparation, the curable composition includes an organosiloxane including an average of at least two silicon-bonded hydrogen atoms per molecule in an amount effective to cure the composition. The curable composition further includes electrically conductive particulate filler such that the electrically conductive adhesive exhibits an electrical conductivity of 0.01, preferably 0.001 or less, ohm-cm and an adhesion strength of at least 3 MPa.

In some embodiments, the first organosiloxane includes an average of at least about one alkenyl groups per molecule. The first organosiloxane may, in some embodiments, include an average of at least 1.05 alkenyl groups per molecule.

In some embodiments, the electrically conductive filler comprising particles having at least on exterior surface of a metal such as nickel, copper, silver, gold, palladium, platinum, and mixtures and alloys thereof. The electrically conductive particle can have any desired shape such as spherical or flake or any aspect ratio in between;

In some embodiments, the curable composition may include an adhesion promoter selected from an organosilane, and organotitanate, and combinations thereof.

A catalyst may be present in a catalytic amount to facilitate the curing of the composition. In some embodiments, the catalyst may be selected from hydrosilylation catalysts including platinum-based catalysts, ruthenium-based catalysts, palladium-based catalysts, osmium-based catalysts, iridium-based catalysts, titanium-based catalysts, and rhodium-based catalysts.

In some embodiments, a reaction inhibitor may be included to inhibit a hydrosilylation reaction of the curable composition. The reaction inhibitor may be selected from acetylenic alcohols, fumarate compounds, maleate compounds, and combinations thereof.

The curable composition may be provided as a one component (1K) composition including all of the components in a single, commercially storage stable composition or a multi-part (2K) composition including a first part and a second or more parts that are initially separate from the first part, wherein the first part does not include the organosiloxane having an average of at least two silicon-bonded hydrogen atoms per molecule. In the multi-part composition, the parts are mixed just before use and the mixture is not commercially storage stable.

In some embodiments, the first organosiloxane may have the following formula:

R¹ₐSiO_{(4-a)/2}
wherein: each R¹ is an alkenyl group or a hydrocarbon having between 1 and 60 carbon atoms; and
   “a” is a positive number between 1.05 and 3.95.

In some embodiments, the first organosiloxane includes at least two unsaturated groups per molecule. The first organosiloxane may exhibit a viscosity of between 0.1 and 100,000 cP at 25 °C at a shear rate of 1 s⁻¹.

In some embodiments, the second organosiloxane may have the following formula:

R²ₐSiO_{(4-a)/2}
wherein: each R² is one of hydrogen, an alkenyl group, or a hydrocarbon having between 1 and 60 carbon atoms; and
   “a” is a positive number between 1.05 and 3.95.

The second organosiloxane may exhibit a viscosity of between 0.1 and 100,000 cP at 25 °C and at a shear rate of 1 s⁻¹. The second organosiloxane can be different than the first organosiloxane.

In another embodiment, an electrically conductive adhesive includes the reaction product of:
(A) an organosiloxane preparation including:
   (i) a first reactive organosiloxane having at least one reactive unsaturated group; and
   (ii) a second reactive organosiloxane including at least about one silicon hydride functional group and at least about one alkenyl group; and
(B) an organosiloxane including an average of at least two silicon-bonded hydrogen atoms per molecule.

At least one of components (A) and (B) may include electrically conductive particulate filler, such that the electrically conductive adhesive exhibits an electrical conductivity of 0.01 ohm-cm or less, preferably 0.001 ohm-cm or less, and an adhesion strength of at least 3 Mpa.

In some multi-part embodiments, components (A) and (B) may be initially separate.

A package of the present invention may include an electronic component and an electrically conductive adhesive adhered to the electronic component. The electrically conductive adhesive may include components (A) and (B) above, along with electrically conductive particulate filler.

A method for making a package in accordance with the present invention includes providing a composition having:
(i) a first reactive organosiloxane including an average of at least about one alkenyl group per molecule, and a second reactive organosiloxane including at least about one silicon hydride functional group and at least about one alkenyl group;
(ii) an unsaturated organosiloxane; and
(iii) an electrically conductive particulate filler in at least one of (i) or (ii).

The method further includes dispensing the composition to a surface of at least one of a substrate and an electronic component, and, optionally in the presence of a catalytic amount of a catalyst, reacting the first part with the second part.

The electronic component may then be secured to the substrate with the composition disposed along an electrically conductive pathway from the electronic component.

In some embodiments, the method further includes curing the composition by exposing the composition to a temperature of up to 300 °C for a cure time period. In some embodiments, the cure time period is less than 2 hours.

### BRIEF DESCRIPTION OF THE DRAWINGS

FIG. 1 is a schematic, cross-sectional view of an electronic package of the present invention.

### DETAILED DESCRIPTION OF THE INVENTION

The objects and advantages enumerated above together with other objects, features, and advances represented by the present invention are now described in terms of detailed embodiments. Other embodiments and aspects of the invention, however, are recognized as being within the grasp of those having ordinary skill in the art.

Generally, an electrically conductive adhesive may be prepared from a curable composition including the following components:
(A) an organosiloxane having an average of at least about one alkenyl group per molecule;
(B) an organosiloxane having at least about one silicon hydride functional group and at least about one alkenyl group;
(C) an organosiloxane containing at least two silicon-bonded hydrogen atoms per molecule;
(D) electrically conductive filler;
(E) a hydrosilylation catalyst; and
(F) optional additional components.

In some embodiments, the curable composition is curable at temperatures of up to 300 °C for a cure period. In some embodiments, the cure period is less than 2 hours. The cured electrically conductive adhesive may exhibit an electrically conductivity 0.01 ohms-cm or less, preferably 0.001 ohms-cm, or less and an adhesion strength of at least 3 MPa.

### Component A

In an embodiment, component (A) has the formula of:

R¹ₐSiO_{(4-a)/2}
wherein: each R¹ is an alkenyl group or a hydrocarbon having between 1 and 60 carbon atoms; and
   “a” is a positive number between 1.05 and 3.95. “a” can be an integer, however for branched molecules “a” can have a fractional (non-integer) value.

Examples of the R¹ alkenyl group or a hydrocarbon having between 1 and 60 carbon atoms, in some embodiments between 2 and 50 carbon atoms, and in some embodiments between 2 and 20 carbon atoms. include alkyl groups such as a methyl group, an ethyl group, a propyl group, a butyl group, a pentyl group, a hexyl group, a heptyl group, an octyl group, a nonyl group, a decyl group, a phenyl group, a dodecyl group, a tetradecyl group, a hexadecyl group, and an octadecyl group; cycloalkyl groups such as a cyclopentyl group and a cyclohexyl group; alkenyl groups such as a vinyl group and an allyl group; aryl groups such as a tolyl group; aralkyl groups such as 2-phenylethyl group and 2-methyl-2-phenylethyl group, and halogenated hydrocarbon groups such as 3,3,3-trifluoropropyl group. The alkenyl groups may be bonded to silicon atoms present at molecular chain terminals and/or silicon atoms present at moieties on the molecular chain other than the terminals.

Component A may have a linear structure, a partially branched linear structure, a branched structure, a cyclic structure, and a three-dimensional network structure such as a silicone resin with functional siloxane monomeric units selected from Me₃SiO, MeSiO₃, SiO₄, and combinations thereof. In an example, a linear diorganopolysiloxane having a main chain having repeating diorganosiloxane units and having both of its molecular chain terminals blocked by triorganosiloxy groups.

Component A may be a polyorganosiloxane having an average, per molecule, of at least 2 aliphatically unsaturated organic groups, which are capable of undergoing a hydrosilylation reaction with a silicon-bonded hydrogen atom of Components B and/or C. In some embodiments, Component A includes at least two reactive alkenyl groups, at least two reactive alkynyl groups, or at least one reactive alkenyl group and at least one reactive alkynyl group. In other embodiments, Component A includes at least one reactive unsaturated group and at least one silicon-bonded hydrogen atom. In some embodiments, Component A includes at least two reactive unsaturated groups and at least one silicon-bonded hydrogen atom.

Component (A) can have a viscosity of about 2 cps to 9,000,000 cps. In some embodiments component (A) can have a viscosity of about 10 cps-100000 cps. In some embodiments component (A) can have a viscosity of about 10 cps-10000 cps.

In some embodiments, Component A may include a polydiorganosiloxane such as dimethylvinylsiloxy-terminated polydimethylsiloxane; dimethylvinylsiloxy-terminated poly(dimethylsiloxane/methylvinylsiloxane); dimethylvinylsiloxy-terminated polymethylvinylsiloxane; trimethylsiloxy-terminated poly(dimethylsiloxane/methylvinylsiloxane, vinyl terminated (phenylmethylsiloxane) vinylphenylsiloxane copolymer, vinyl terminated (diphenylsiloxane) dimethylsiloxane copolymer, vinyl terminated (diphenylsiloxane)-dimethylsiloxane copolymer, (phenylmethylsiloxane) vinylphenylsiloxane copolymer, (phenylmethylsiloxane) vinylmethylsiloxane copolymer, and combinations thereof.

### Component B

In an embodiment, component (B) has the formula of:

R²ₐSiO_{(4-a)/2}
wherein: each R² is one of hydrogen, an alkenyl group, or a hydrocarbon having between 1 and 60 carbon atoms; and
   “a” is a positive number between 1.05 and 3.95. “a” can be an integer, however for branched molecules “a” can have a fractional (non-integer) value.
   Component B can be different than component A.

Examples of the R² alkenyl group or a hydrocarbon having between 1 and 60 carbon atoms, in some embodiments between 2 and 50 carbon atoms, and in some embodiments between 2 and 20 carbon atoms. include alkyl groups such as a methyl group, an ethyl group, a propyl group, a butyl group, a pentyl group, a hexyl group, a heptyl group, an octyl group, a nonyl group, a decyl group, a phenyl group, a dodecyl group, a tetradecyl group, a hexadecyl group, and an octadecyl group; cycloalkyl groups such as a cyclopentyl group and a cyclohexyl group; alkenyl groups such as a vinyl group and an allyl group; aryl groups such as a tolyl group; aralkyl groups such as 2-phenylethyl group and 2-methyl-2-phenylethyl group, and halogenated hydrocarbon groups such as 3,3,3-trifluoropropyl group. The alkenyl groups may be bonded to silicon atoms present at molecular chain terminals and/or silicon atoms present at moieties on the molecular chain other than the terminals. Component B may have a linear structure, a partially branched linear structure, a branched structure, a cyclic structure, and a three-dimensional network structure such as a silicone resin with functional siloxane monomeric units selected from Me₃SiO, MeSiO₃, SiO₄, and combinations thereof. In an example, a linear diorganopolysiloxane having a main chain having repeating diorganosiloxane units and having both of its molecular chain terminals blocked by triorganosiloxy groups.

Component B may be a polyorganosiloxane having an average, per molecule, of at least one reactive silicon hydride and at least one alkenyl group. In some embodiments, Component B includes at least one silicon-bonded hydrogen atom and at least one reactive unsaturated group per molecule. In some embodiments, Component B includes at least one silicon-bonded hydrogen atom and at least two reactive unsaturated groups per molecule. Typically, the alkenyl group will be at a terminal position on the molecule and the hydride group can be terminal or pendant.

Component (B) can have a viscosity of about 2 cps to 9,000,000 cps. In some embodiments component (B) can have a viscosity of about 10 cps-100000 cps. In some embodiments component (B) can have a viscosity of about 10 cps-10000 cps.

### Component C

In an embodiment, component (C) has the formula of:

R³ₐSiO_{(4-a)/2}
wherein: each R³ is one of hydrogen or a hydrocarbon having between 1 and 60 carbon atoms; and
   “a” is a positive number between 1.05 and 3.95. “a” can be an integer, however for branched molecules “a” can have a fractional (non-integer) value.
   Component C can be different than component A and/or component B.

Examples of the R³ hydrocarbons having between 1 and 60 carbon atoms, in some embodiments between 2 and 50 carbon atoms, and in some embodiments between 2 and 20 carbon atoms. include alkyl groups such as a methyl group, an ethyl group, a propyl group, a butyl group, a pentyl group, a hexyl group, a heptyl group, an octyl group, a nonyl group, a decyl group, a phenyl group, a dodecyl group, a tetradecyl group, a hexadecyl group, and an octadecyl group; cycloalkyl groups such as a cyclopentyl group and a cyclohexyl group.

Component C may have a linear structure, a partially branched linear structure, a branched structure, a cyclic structure, and a three-dimensional network structure such as a silicone resin with functional siloxane monomeric units selected from Me₃SiO, MeSiO₃, SiO₄, and combinations thereof. In an example, a linear diorganopolysiloxane having a main chain having repeating diorganosiloxane units and having both of its molecular chain terminals blocked by triorganosiloxy groups.

Component C may be a polyorganosiloxane having an average, per molecule, of at least two silicon-bonded hydrogen atoms, typically between 2 and 300 silicon-bonded hydrogen atoms, and preferably between 2 and 100 silicon-bonded hydrogen atoms. The hydrogen atoms in Component C may be bonded to silicon atoms present at molecular chain terminals and/or silicon atoms present at moieties on the molecular chain other than the terminals.

Organic groups other than the hydrogen atoms may be bonded to silicon atoms as well.

Examples of such organic groups include alkyl groups such as a methyl group, an ethyl group, a propyl group, a butyl group, a pentyl group, a hexyl group and a heptyl group; aryl groups such as a phenyl group, a tolyl group, a xylyl group and a naphthyl group; aralkyl groups such as a benzyl group and a phenethyl group; and halogenated alkyl groups such as a chloromethyl group.

In some embodiments, components A, B, and C together are present in an amount of between 1 and 50 wt. % of the curable composition. In some embodiments, components A, B, and C together are present in an amount of between 2 and 30 wt. % of the curable composition. In some embodiments, components A, B, and C together are present in an amount of between 5 and 20 wt. % of the curable composition. In some embodiments, components A, B, and C together are present in an amount of between 10 and 15 wt. % of the curable composition.

In some embodiments, component C is present in an amount of between 0.5 and 99.5% relative to a total amount of components A, B, and C together in the curable composition. In some embodiments, component C is present in an amount of between 0.5 and 50% relative to a total amount of components A, B, and C together in the curable composition. In some embodiments, component C is present in an amount of between 0.5 and 10% relative to a total amount of components A, B, and C together in the curable composition. In some embodiments, component C is present in an amount of between 1 and 5% relative to a total amount of components A, B, and C together in the curable composition.

In some embodiments, the reaction product of the silicone resins of components A, B, and C are heat curable. In some embodiments, the heat cure is a hydrolysis-polymerization reaction at temperatures of up to 300 °C. Thus, electronic devices of the packages of the present invention may be adhered to a substrate at temperatures of 300 °C or lower.

In some embodiments, a ratio of silicon-bonded hydrogen atoms to vinyl groups in the curable composition is between 0.1:1 and 100:1. In some embodiments, a ratio of silicon-bonded hydrogen atoms to vinyl groups in the curable composition is between 0.5:1 and 50:1. In some embodiments, a ratio of silicon-bonded hydrogen atoms to vinyl groups in the curable composition is between 1:1 and 10:1. In some embodiments, a ratio of silicon-bonded hydrogen atoms to vinyl groups in the curable composition is between 1.2:1 and 5:1.

### Component D

Component (D) is a particulate filler having an electrical conductivity of 0.01 ohms-cm or less, preferably 0.001 ohms-cm or less. In some embodiments, the particulate filler has an average particle size (d₅₀) of between 0.1 and 250 μm. In some embodiments, the particulate filler has an average particle size (d₅₀) of between 0.1 and 100 μm. In some embodiments, the particulate filler has an average particle size (d₅₀) of between 0.2 and 100 μm. In some embodiments, the distribution of electrically conductive particulate filler is not a mono dispersion, but rather a particle size distribution. In some embodiments, the particle size distribution is multi-modal, including a mixture of relatively small particles and relatively large particles, within the size ranges described above. For the purposes hereof, the term “average particle size” refers to a cumulative weight average value (d₅₀) in which 50% of the particles are larger than the value, and 50% of the particles are smaller than the value, as determined by laser light diffraction. Component D may be dispersed in the polymer matrix. Examples of electrically conductive particulate filler include particles or powders at least partially comprised of a metal such as nickel, copper, silver, gold, platinum, palladium, aluminum, diamond, carbon, indium, gallium, and mixtures and alloys thereof. In some embodiments, the particulate filler may be electrically conductive by having at least an outer surface of a metal selected from nickel, copper, silver, gold, platinum, palladium, and alloys thereof. The shape of the particulate filler may be spherical, aspherical, and combinations thereof. Example aspherical shapes include flake-like, plate-like, rod-like, wire-like and so on. Spherical particulate filler may have an aspect ratio of between 0.8-1.2.

The electrically conductive particulate filler is present in an amount sufficient to provide an electrical current path between the adhered parts. In some embodiments, the adhesive exhibits an electrical conductivity of 0.001 ohms-cm or less. In some embodiments, the adhesive exhibits an electrical conductivity of 0.0001 ohms-cm or less. In some embodiments, the adhesive exhibits an electrical conductivity of 0.00001 ohms-cm or less.

In order to achieve the high electrical conductivity values, the electrically conductive particulate filler may be present in an amount of at least 60 wt. % of the adhesive. In some embodiments, the electrically conductive filler may be present in an amount of between 60 and 95 wt. % of the adhesive. In some embodiments, the electrically conductive filler may be present in an amount of between 70 and 90 wt. % of the adhesive. In some embodiments, the electrically conductive filler may be present in an amount of between 75 and 85 wt. % of the adhesive.

If necessary, component D may also be hydrophobized with, for example, organosilane, organosilazane, organopolysiloxane, and an organic fluorine compound.

### Component E

Component (E) is a catalyst effective for catalyzing a hydrosilylation reaction. The catalyst of component E may be selected from a platinum-based catalyst, a ruthenium-based catalyst, a palladium-based catalyst, an osmium-based catalyst, an iridium-based catalyst, a titanium-based catalyst, and a rhodium-based catalyst. In some embodiments, the composition of the present invention may be converted to a curable composition with the presence of the catalyst of component E. However, it is contemplated that the curable compositions of the present invention do not require component E for reaction.

In the compositions of the present disclosure, component E is present in an amount required for curing the composition, which is referred to as the catalytic amount. In some embodiments, component E may be present in an amount of between 0.1 and 1000 ppm mass of the organosiloxane. In some embodiments, component E may be present in an amount of between 0.1 and 500 ppm mass of the organosiloxane. In some embodiments, component E may be present in an amount of between 0.1 and 100 ppm mass of the organosiloxane. In some embodiments, component E may be present in an amount of between 1 and 50 ppm mass of the organosiloxane. In some embodiments, component E may be present in an amount of between 15 and 35 ppm of the organosiloxane.

In order to control the curing speed of the composition of the present disclosure, a curing reaction inhibitor may be included in the curable composition. Inhibitors useful in the present invention include inhibitors for hydrosilylation, such as acetylene-based compounds including acetylenic alcohols, fumarate-based compounds, and maleate-based compounds. Although there are no limitations on the amount of curing reaction inhibitor used in the compositions, example amounts include between 2 and 20,000 ppm mass of the organosiloxane. In some embodiments, the curing reaction inhibitor is present in an amount of between 20 and 5,000 ppm mass of the organosiloxane. In some embodiments, the curing reaction inhibitor is present in an amount of between 300 and 3,500 ppm mass of the organosiloxane in the compositions of the present invention.

In some embodiments, a ratio by mass of curing reaction inhibitor to reaction catalyst may be between 10:1 and 500:1. In some embodiments, a ratio by mass of curing reaction inhibitor to reaction catalyst may be between 20:1 and 200:1. In some embodiments, a ratio by mass of curing reaction inhibitor to reaction catalyst may be between 35:1 and 100:1.

The electrically conductive compositions of the present disclosure may further include one or more additional components, such as an adhesion promoter, a silicone diluent, a reactive diluent, a colorant, a corrosion inhibitor, an acid acceptor, silica, carbon black, glass beads, metal particles, and combinations thereof. In some embodiments, one or more adhesion promotors may be present in an amount effective for building chemical bonding at an interface between the electrically conductive adhesive and adhered substrates. Adhesion promoters may be present in the compositions of the present invention in an amount of between 0 and 5 wt. % of the composition. In some embodiments, an adhesion promoter is present in an amount of between 0 and 2 wt. % of the composition. In some embodiments, an adhesion promoter is present in an amount of between 0.1 and 0.5 wt. % of the composition.

Examples of suitable adhesion promoters include organosilanes including monosilanes, dipodal silanes, tripodal silanes, and oligomer silanes with methoxy, ethoxy, and/or propyloxy structure. An example alkoxysilane is as an epoxy-functional alkoxysilane. Other suitable adhesion promoters include organotitanates and mercapto-functional compounds.

Solvents may optionally be used in some embodiments. Preferably, the composition is free of solvents such as organic solvents to minimize volatile organic compound (VOC) content.

The electrically conductive compositions of the present disclosure may be used after being cured. In some embodiments, the electrically conductive compositions of the present disclosure may be cured at a temperature from about room temperature to about 300 °C. In some embodiments, the electrically conductive compositions of the present disclosure may be cured when heated to a temperature of between 70 °C to about 200 °C. In some embodiments, the electrically conductive compositions of the present disclosure may be cured when heated to a temperature of between 125 °C to 190 °C.

A curing time may be at least one minute. In some embodiments, the curing time is less than 250 minutes. In some embodiments, the curing time is between 1 and 200 minutes. In some embodiments, the curing time is between 1 and 150 minutes.

The curable compositions of the present disclosure may be provided as a one-part (1K) composition or a multi-part composition including the components in two or more parts, provided that components B, C, and E are not present in the same part. For a one-part composition the components are mixed together with sufficient reaction inhibitor so that the resulting composition has a commercially acceptable storage time of weeks to one or more years while remaining useful. For a multipart composition, component E cannot be present with component B or C in the same part. Typically in a multipart composition any catalyst would be in the alkenyl silane component and separated from any hydride component.

The curable silicone compositions of the present disclosure may exhibit adjustable rheological performance and curing kinetics adapting to different processing in packaging applications, and low volatile organic compound (VOC) content. Moreover, the present silicone composition is curable to form a silicone adhesive having both excellent adhesion and electrical conductivity, as well as good reliability.

The cured adhesives of the present invention preferably exhibit an adhesion strength of at least 3 MPa. In some embodiments, the cured adhesives exhibit an adhesion strength of at least 5 MPa. In some embodiments, the cured adhesives exhibit an adhesion strength of at least 10 MPa. In some embodiments, the cured adhesives exhibit an adhesion strength of at least 20 MPa. The adhesion strength of the adhesives of the present invention is measured by the die shear test. In some embodiments, the die shear test may be performed by the Mil-Std-883 Method 2019.

The silicone compositions of the present invention are useful for preparing electrically conductive adhesives, which may be used in various applications, such as adhesives in semiconductor packaging, die attach adhesives, and solder replacements. In a particular embodiment, the adhesives of the present disclosure may be useful for bonding electronic components to flexible or rigid substrates.

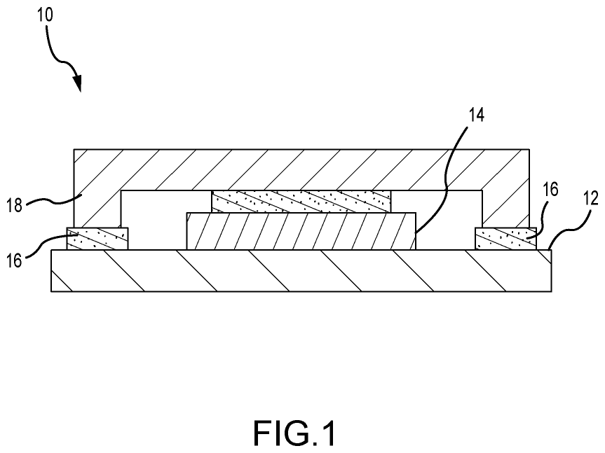

FIG. 1 schematically illustrates a package 10 of the present invention including a substrate 12, such as a printed circuit board; an electronic component 14, such as a semiconductor, processor, or the like; electrically conductive adhesive 16; and a lead 18. The electrically conductive adhesive 16 is adhered between substrate 12 and lead 18. Once cured, the adhesive bonds the substrate 12 and lead 18 while providing electrical contact between the substrate 12 and lead 18. In other embodiments, electrically conductive adhesive 16 may replace solder to provide a secure and electrically transmissive connection between two or more electrical components. The electrically conductive adhesive is curable at low temperatures and would be useful in applications where the temperature required to melt solder is problematic.

In one embodiments, a curable composition of the present invention is dispensed to a surface of at least one of the substrate 12 and lead 18, and the lead 18 is secured to the substrate 12 with the curable composition disposed therebetween, so that the composition bonds the substrate 12 and lead 18 while providing an electrically conductive pathway from substrate 12 to lead 18. In some embodiments, package 10 is formed by curing the composition for a cure time to establish a cured adhesive exhibiting a form-stable product. The composition may be cured by exposing the composition to a temperature of up to 300 °C for a cure time period of less than 2 hours.

### EXAMPLES

The following test methods were used in the Examples. Viscosity was measured using a Brookfield viscosimeter with Cone plate, CP-51 at 5 rpm and room temperature. Adhesion strength was measured on a Dage series 4000 die shear tester using a 3 mm by 3 mm silicon die and a nickel-coated copper substrate at room temperature. Electrical conductivity of the bulk cured material was measured as the volume resistivity, which was tested using a four-point probe on a Megohm bridge.

### Example 1

A one-part formulation was prepared in accordance with the following Table:

| Material | Weight (%) |
|---|---|
| SILQUEST A-174NT | 0.02 |
| SILQUEST A-187 | 1.2 |
| 3-Aminopropyltrimethoxysilane | 0.1 |
| (3-triethoxylsilyl)propylsuccinic | 0.2 |
| anhydride | |
| Dimethyl Maleate | 0.4 |
| Methyl hydrosiloxane dimethyl | 3.25 |
| siloxane copolymer | |
| Vinyl methyl dimethyl siloxane | 14.828 |
| copolymer | |
| Silver filler (Flake) | 80 |
| Pt catalyst | 0.002 |

The methyl hydrosiloxane dimethyl siloxane copolymer contains an average of 5.55 mmol/g of Si—H, the Vinyl methyl dimethyl siloxane copolymer contains an average of 0.36 mmol/g of Vinyl functional group. The silver flake has a tap density ~3.2 g/cm3, and specific surface area ~0.47 m2/g, average diameter ~8 um (with D50~5.8) with fatty acid surface treatment.

The components were mixed in a double planetary mixer for 10 minutes under vacuum and cooling with chilled water. The viscosity of the final formulation is ~22 Pa*s at 5 rpm. The mixed composition was cured by exposure to 150 °C for two hours. The cured silicone adhesive exhibited an adhesion strength between a silicon wafer and a nickel substrate of 4.7 MPa at room temperature, The cured silicone adhesive exhibited a volume resistance of 0.0003 ohms-cm.

### Example 2

A one-part formulation was prepared in accordance with the following Table:

| Material | Weight (%) |
|---|---|
| SILQUEST A-174NT | 0.012 |
| SILQUEST A-187 | 0.72 |
| 3-Aminopropyltrimethoxysilane | 0.06 |
| (3-triethoxylsilyl)propylsuccinic | 0.12 |
| anhydride | |
| Dimethyl Maleate | 0.24 |
| Methyl hydrosiloxane dimethyl | 1.95 |
| siloxane copolymer | |
| Vinyl methyl dimethyl siloxane | 8.8968 |
| copolymer | |
| Silver filler (Flake) | 88 |
| Pt catalyst | 0.0012 |

The Methyl hydrosiloxane dimethyl siloxane copolymer contains an average of 5.55 mmol/g of Si—H, the Vinyl methyl dimethyl siloxane copolymer contains an average of 0.36 mmol/g of Vinyl functional group. The silver flake has a tap density ~6.3 g/cm3, and specific surface area ~0.31 m2/g, diameter ranged from ~0.7 to 20 um (with D50~2.2) with fatty acid surface treatment.

The components were mixed in a double planetary mixer for 10 minutes under vacuum and cooling with chilled water. The viscosity of the final formulation is ~15 Pa*s at 5 rpm. The mixed composition was cured by exposure to 150 °C for two hours. The cured silicone adhesive exhibited an adhesion strength between a silicon wafer and a nickel substrate of 5.4 MPa at room temperature, The cured silicone adhesive exhibited a volume resistance of 0.00015 ohms-cm.

1. A curable composition for preparing an electrically conductive adhesive, the curable composition comprising:
an organosiloxane preparation including:
(i) a first reactive organosiloxane having at least one unsaturated group; and
(ii) a second reactive organosiloxane including at least about one silicon hydride functional group and at least about one alkenyl group;
an organosiloxane including an average of at least two silicon-bonded hydrogen atoms per molecule, the organosiloxane being present in an amount effective to cure the composition; and
electrically conductive particulate filler, wherein the electrically conductive adhesive exhibits an electrical conductivity of 0.01 ohms-cm or less and an adhesion strength of at least 3 MPa.

2. The curable composition as in claim 1 wherein the first reactive organosiloxane includes an average of at least about one alkenyl group per molecule.

3. The curable composition as in claim 2 wherein the first reactive organosiloxane includes an average of at least 1.05 alkenyl groups per molecule.

4. The curable composition as in claim 2 wherein the first reactive organosiloxane is absent a silicone hydride functional group.

5. The curable composition as in claim 2 wherein the first reactive organosiloxane is present in an amount effective to cure the organosiloxane preparation.

6. The curable composition as in claim 1 wherein the electrically conductive particulate filler is particles at least partially comprised from nickel, copper, silver, gold, palladium, platinum, and mixtures and alloys thereof.

7. The curable composition as in claim 1, including an adhesion promoter selected from an organosilane, an organotitanate, and combinations thereof.

8. The curable composition as in claim 1, including a hydrosilylation catalyst present in a catalytic amount.

9. The curable composition as in claim 1, including a reaction inhibitor effective to inhibit a hydrosilylation reaction.

10. The curable composition as in claim 9 wherein the reaction inhibitor is selected from acetylenic alcohols, fumarate compounds, maleate compounds, and combinations thereof.

11. The curable composition as in claim 1, including a first part and a second part that is initially separate from the first part, wherein one of the first part and the second part does not include the organosiloxane including an average of at least two silicon-bonded hydrogen atoms per molecule.

12. The curable composition as in claim 1, wherein the first reactive organosiloxane has the following formula:
R¹ₐSiO_{(4-a)/2}
wherein: each R¹ is an alkenyl group or a hydrocarbon having between 1 and 60 carbon atoms; and
“a” is a positive number between 1.05 and 3.95.

13. The curable composition as in claim 12 wherein the first reactive organosiloxane includes at least two reactive unsaturated groups per molecule.

14. The curable composition as in claim 8, wherein the hydrosilylation catalyst is selected from the group consisting of platinum-based catalysts, ruthenium-based catalysts, palladium-based catalysts, osmium-based catalysts, iridium-based catalysts, titanium-based catalysts, and rhodium-based catalysts.

15. The curable composition as in claim 12 wherein the second reactive organosiloxane has the following formula:
R²ₐSiO_{(4-a)/2}
wherein: each R² is one of hydrogen, an alkenyl group, or a hydrocarbon having between 1 and 60 carbon atoms; and
“a” is a positive number between 1.05 and 3.95.

16. The curable composition as in claim 15 wherein the first reactive organosiloxane exhibits a viscosity of between 0.1 and 100,000 cP at 25 °C at a shear rate of 1 s⁻¹ and wherein the second reactive organosiloxane exhibits a viscosity of between 0.1 and 100,000 cP at 25 °C at a shear rate of 1 s⁻¹.

17. An electrically conductive adhesive comprising the reaction product of:
(A) an organosiloxane preparation including:
(i) a first reactive organosiloxane having at least one reactive unsaturated group; and
(ii) a second reactive organosiloxane including at least about one silicon hydride functional group and at least about one alkenyl group; and
(B) an organosiloxane including an average of at least two silicon-bonded hydrogen atoms per molecule,
wherein at least one of components (A) and (B) include electrically conductive particulate filler, such that the electrically conductive adhesive exhibits an electrical conductivity of 0.001 ohms-cm or less and an adhesion strength of at least 3 MPa.

18. The electrically conductive adhesive as in claim 17 wherein components (A) and (B) are initially separate.

19. A package, comprising:
an electronic component; and
the electrically conductive adhesive of claim 15 adhered to the electronic component.

20. The package as in claim 17, including a substrate, wherein the electrically conductive adhesive is adhered between the electronic component and the substrate.

21. A method for making a package, the method comprising:
(a) providing a composition, comprising:
(i) a first part, including a first reactive organosiloxane including an average of at least about one alkenyl groups per molecule, and a second reactive organosiloxane including at least about one silicon hydride functional group and at least about one alkenyl group;
(ii) a second part, including an unsaturated organosiloxane; and
(iii) electrically conductive particulate filler in at least one of the first part and the second part;
(b) dispensing the composition to a surface of at least one of a substrate and an electronic component;
(c) optionally in the presence of a catalytic amount of a catalyst, reacting the first part with the second part; and
(d) securing the electronic component to the substrate with the composition disposed therebetween along an electrical pathway from the electronic component.

22. The method as in claim 21 wherein the composition exhibits an electrical conductivity of 0.001 ohms-cm or less.

23. The method as in claim 21, including curing the composition by exposing the composition to a temperature of up to 300 °C for a cure time period.

24. The method as in claim 23 wherein the cure time period is less than 2 hours.
